(19) United States
(12) Patent Application Publication
(10) Pub. No.: US 2025/0357155 A1
(43) Pub. Date: Nov. 20, 2025

(54) SUBSTRATE BONDING APPARATUS

(71) Applicant: Samsung Electronics Co., Ltd., Suwon-si (KR)

(72) Inventors: In Hwa Baek, Suwon-si (KR); Se Hyun Lee, Cheonan-si (KR); Sang Hoon Park, Cheonan-si (KR)

(73) Assignee: SEMES CO., LTD, Cheonan-si (KR)

(21) Appl. No.: 18/938,714

(22) Filed: Nov. 6, 2024

(30) Foreign Application Priority Data
May 20, 2024 (KR) 10-2024-0065111

(51) Int. Cl. H01L 21/67; H01L 21/683; H01L 21/687

(52) U.S. Cl. CPC H01L 21/67092; H01L 21/67017; H01L 21/67259; H01L 21/6838; H01L 21/68785

(57) ABSTRACT

Disclosed is a substrate bonding apparatus including: a deformable plate configured to support a first substrate thereon and to be at least partially deformable; a first chuck on one surface of the deformable plate such that a first space is defined between the deformable plate and the first chuck, wherein the first chuck has a diameter larger than a diameter of the first substrate; and a fluid control unit configured to control inflow and outflow of fluid into and out of the first space, wherein the fluid control unit is configured to control the inflow and the outflow of the fluid into and out of the first space so that a negative pressure is applied to the first space.

### CROSS-REFERENCE TO RELATED APPLICATION

This application claims priority under 35 U.S.C. 119 from Korean Patent Application No. 10-2024-0065111, filed on May 20, 2024 in the Korean Intellectual Property Office, the disclosure of which is herein incorporated by reference in its entirety.

### FIELD

The present disclosure relates to a substrate bonding apparatus.

### BACKGROUND

Previously, a main focus in semiconductor technology was to increase the integration density. However, as the improvement in the integration density of a semiconductor device reaches its limit, 3D package technology that stacks the semiconductor devices three-dimensionally is gaining attention. Using a vertical stacking scheme, a large number of semiconductor devices may be implemented in the same silicon area, thereby lowering a manufacturing cost and increasing performance.

Several methods may be used to create a 3D IC. Representative examples thereof include “Chip-to-Chip (C2C) bonding”, “Wafer-to-Wafer (W2W) bonding”, and “Chip-to-Wafer (C2W) bonding”. In the C2C bonding scheme, the wafer is cut into chips and then the chips are bonded to each other. In the C2W bonding scheme, a wafer is cut into chips, and then, the chips are bonded to a substrate wafer. The C2C and C2W take a long process time, and increase a manufacturing cost.

The W2W bonding scheme refers to a scheme of aligning and contacting two or more substrates with each other and then bonding the two or more substrate to each other. The W2W bonding scheme bonds the substrates to each other and cuts the bonded substrates into chips at once, and thus has high productivity due to a short manufacturing process time.

However, in the wafer-to-wafer (W2W) bonding scheme, when bonding two substrates to each other, the two substrates are bonded to each other while being in a flat state, such that bubbles may be generated between the two substrates. Since the air bubbles can cause a chip short-circuit, a chip yield may be reduced or additional processes may be required.

To solve this problem, a scheme is used in which a lower substrate of the two hydrophilic treated substrates is provided in a convex hemispherical shape, and then an upper substrate thereof is first bonded to the lower substrate in a point contact manner therewith and then the two substrates are bonded to each other in a direction from edges of the substrates to centers thereof.

In this bonding scheme, a deformable plate supporting the substrate is deformed into a convex hemisphere shape in order to deform the substrate into the convex hemisphere shape. High-pressure fluid such as compressed air is used to deform the deformable plate into the convex hemispherical shape. When the high-pressure fluid is used, the fluid may press the plate in an upward direction such that the deformable plate may be removed from a chuck. For this reason, a clamp structure connecting the chuck and the deformable plate to each other may be used but causes a substrate support apparatus to be complicated. Distortion of the substrate may occur due to pressure application around the clamp structure, which may cause a problem related to a substrate scale-compensation.

In addition, when a positive pressure is provided across the chuck and the deformable plate to change a shape of the deformable plate, fluid leaks through a gap between the chuck and the deformable plate, thereby making fluid control difficult and requiring improvement.

### SUMMARY

A purpose of the present disclosure is to provide a substrate bonding apparatus with a simple structure and high structural reliability.

Purposes according to the present disclosure are not limited to the above-mentioned purpose. Other purposes and advantages according to the present disclosure that are not mentioned may be understood based on following descriptions, and may be more clearly understood based on example embodiments according to the present disclosure. Further, it will be easily understood that the purposes and advantages according to the present disclosure may be realized as shown in the claims or combinations thereof.

One aspect of the present disclosure provides a substrate bonding apparatus including: a deformable plate configured to support a first substrate thereon and to be at least partially deformable; a first chuck on one surface of the deformable plate such that a first space is defined between the deformable plate and the first chuck, wherein the first chuck has a diameter larger than a diameter of the first substrate; and a fluid control unit configured to control inflow and outflow of fluid into and out of the first space, wherein the fluid control unit is configured to control the inflow and the outflow of the fluid into and out of the first space so that a negative pressure is applied to the first space.

Another aspect of the present disclosure provides a substrate bonding apparatus including: a lower module configured to support a first substrate; and an upper module including a second chuck configured to support a second substrate facing the first substrate, wherein the lower module includes: a deformable plate configured to support the first substrate thereon and to be at least partially deformable; a first chuck under the deformable plate such that a first space is defined between the deformable plate and the first chuck, wherein the first chuck has a diameter larger than a diameter of the first substrate; and a fluid control unit configured to control inflow and outflow of fluid into and out of the first space, wherein the fluid control unit is configured to control the inflow and the outflow of the fluid into and out of the first space so that a negative pressure is applied to the first space.

Still another aspect of the present disclosure provides a substrate bonding apparatus for bonding a plasma-treated first substrate and a plasma-treated second substrate to each other, the apparatus including: a lower module including a first chuck having a larger diameter than a diameter of the first substrate, wherein the first chuck is under the first substrate; and an upper module including a second chuck configured to support the second substrate facing the first substrate, wherein the lower module includes: a deformable plate on top of the first chuck and configured to support the first substrate thereon and to be at least partially deformable, wherein a first space is defined between the deformable plate and the first chuck; and a fluid control unit configured to control inflow and outflow of fluid into and out of the first space, wherein the deformable plate includes a step between a middle area and a center area, and a step between an edge area and the middle area, wherein a thickness of the deformable plate decreases step by step in a radial outward direction, wherein the deformable plate includes a first support in contact with the first chuck and disposed on the center area, wherein the deformable plate includes a second support extending downwardly from the edge area toward the first chuck and extending along the edge area, wherein the deformable plate includes a position in the edge area at which the edge area has been depressed down by a greatest amount, wherein the position vertically overlaps an edge of the first substrate or vertically overlaps a position positioned radially outwardly of the edge of the first substrate, wherein the deformable plate includes a first scale-compensation area and a second scale-compensation area arranged in a circumferential direction of the edge area of the deformable plate, wherein the first scale-compensation area has a smaller thickness than a thickness of the second scale-compensation area, wherein the fluid control unit includes a first line in communication with the first space, and a vacuum pump connected to the first line, wherein the vacuum pump is configured to discharge the fluid out of the first space so that the deformable plate is partially depressed down, wherein the first chuck includes an edge ring surrounded by the second support and a sensor unit configured to detect a vertical level of the deformable plate, wherein the sensor unit includes: a first sensor on an upper surface of the first chuck and at a position vertically overlapping the edge of the first substrate; and a first sensing target defining a sensing target surface to be sensed by the first sensor and on a lower surface of the deformable plate.

Specific details of other embodiments are included in the detailed description and drawings.

The substrate bonding apparatus according to the present disclosure is free of the clamp and thus has a simplified structure, and does not cause fluid leakage out of a space under the deformable plate or deterioration of alignment accuracy due to clamp plane management.

The substrate bonding apparatus according to the present disclosure deforms the deformable plate using the negative pressure such that deterioration in fluid control precision due to the fluid leakage is prevented, and the risk of explosion and/or damage due to pressure application is low, thereby improving structural reliability.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF DRAWINGS

The above and other aspects and features of the present disclosure will become more apparent by describing in detail example embodiments thereof with reference to the attached drawings, in which:

FIG. 1 is a plan view for illustrating a substrate treating system according to some embodiments of the present disclosure;

FIG. 2 is a front view for illustrating a substrate bonding apparatus according to some embodiments of the present disclosure;

FIG. 3 is a diagram showing an area A in FIG. 2;

FIG. 4 is a diagram showing an area B in FIG. 3;

FIG. 5 is a diagram showing a state in which centers of a first substrate and a second substrate are bonded to each other in the substrate bonding apparatus according to some embodiments of the present disclosure;

FIG. 6 is a diagram showing an upper space shape of a deformable plate of the substrate bonding apparatus according to some embodiments of the present disclosure;

FIG. 7 is a diagram showing a process of attaching the second substrate to the first substrate in the substrate bonding apparatus according to some embodiments of the present disclosure;

FIG. 8 is a diagram for illustrating a state in which the first substrate and the second substrate have been bonded to each other in the substrate bonding apparatus according to some embodiments of the present disclosure;

FIG. 9 is a diagram showing a state in which lift pins protrude in the substrate bonding apparatus according to some embodiments of the present disclosure;

FIG. 10 is a diagram for illustrating a substrate bonding apparatus according to some embodiments of the present disclosure;

FIG. 11 is a diagram for illustrating a lower module of the substrate bonding apparatus according to some embodiments of the present disclosure;

FIG. 12 is a diagram for illustrating a deformable plate of a substrate bonding apparatus according to some embodiments of the present disclosure;

FIG. 13 is a diagram for illustrating a saddle substrate;

FIG. 14 is a plan view showing an upper module according to some embodiments of the present disclosure;

FIG. 15 is a diagram showing the second substrate corresponding to a cutting surface of II-II′ in FIG. 14;

FIG. 16 is a diagram showing a ratio between areas in a plan view of the first substrate and the second substrate in a flat state;

FIG. 17 is a diagram showing a state in which the first substrate is brought into a convex state by the deformable plate;

FIG. 18 is a diagram for illustrating a deformable plate of a substrate bonding apparatus according to some embodiments of the present disclosure; and

FIG. 19 is a diagram for illustrating a deformable plate of a substrate bonding apparatus according to some embodiments of the present disclosure.

### DETAILED DESCRIPTION

Advantages and features of the present disclosure, and a method of achieving the advantages and features will become apparent with reference to example embodiments described in detail below together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform the same or similar functionality. Further, descriptions and details of well-known steps and elements may be omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers, sections and/or periods, these elements, components, regions, layers, sections and/or periods should not be limited by these terms. These terms are used to distinguish one element, component, region, layer, section or period from another element, component, region, layer, section or period. Thus, a first element, component, region, layer, section or period as described herein could be termed a second element, component, region, layer, section or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

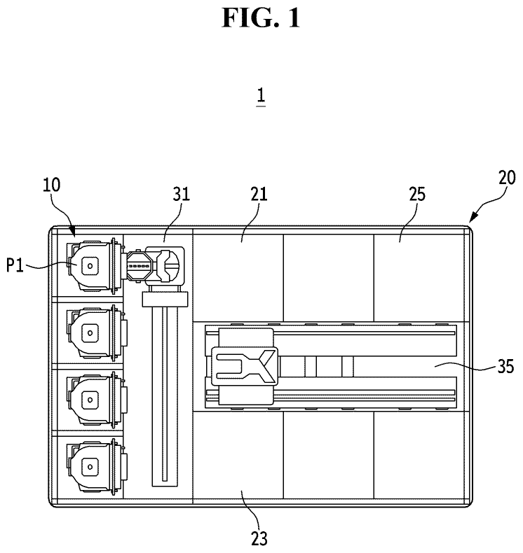

FIG. 1 is a plan view for illustrating a substrate treating system according to some embodiments of the present disclosure.

Referring to FIG. 1, a substrate treating system 1 according to some embodiments of the present disclosure may be composed of a room with an inner space and may include an index module 10 and a process module 20.

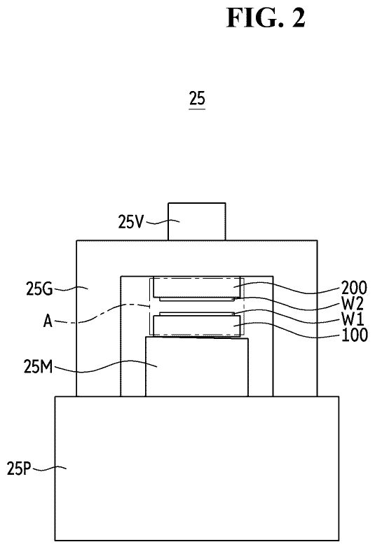

The index module 10 may receive first and second substrates W1 and W2 (see FIG. 2) from the outside and transfer the substrates W1 and W2 to the process module 20. The index module 10 may be an equipment front end module equipped with a load port.

A container P1 containing therein the substrates W1 and W2 may be placed on the load port. The container P1 may be a front opening unified pod (FOUP). The container P1 may be brought from the outside into the load port or taken out from the load port into the outside by an overhead transfer (OHT).

A first transfer module 31 may be disposed between the index module 10 and the process module 20. The first transfer module 31 may transfer the substrates W1 and W2 between the container P1 disposed in the load port and the process module 20. The first transfer module 31 may include an index robot that moves on an index rail.

The process module 20 may include a plurality of process chambers 21, 23, and 25. A second transfer module 35 may be disposed between the plurality of process chambers 21, 23, and 25. A transfer robot of the second transfer module 35 may transfer the substrates W1 and W2 to a preset process chamber 21, 23 or 25 among the plurality of process chambers 21, 23, and 25. For example, the transfer robot of the second transfer module 35 may transfer the substrates W1 and W2 from one process chamber (e.g., 23) among the plurality of process chambers 21, 23, and 25 to another process chamber (e.g., 25).

The plurality of process chambers 21, 23, and 25 may be arranged in a line, or may be stacked vertically, or may have a combination arrangement thereof. As shown in FIG. 1, some process chambers 21 and 25 and the other process chamber 23 may be respectively disposed on both opposing sides of the second transfer module 35. The arrangement of the plurality of process chambers 21, 23, and 25 is not limited to the above-described example, and may vary based on the footprint or process efficiency of the substrate treating system 1.

The plurality of process chambers 21, 23, and 25 may include a plasma treating apparatus 21, a cleaning apparatus 23, and a substrate bonding apparatus 25.

The plasma treating apparatus 21 may perform plasma treating on a surface of at least one of the two substrates W1 and W2. That is, the plasma treating apparatus 21 may be embodied as a treating apparatus for making at least one of to-be-bonded surfaces of the first substrate W1 and the second substrate W2 hydrophilic via plasma treatment.

The plasma treating apparatus 21 may irradiate plasma to the surfaces of the substrates W1 and W2 disposed in an induced coupled plasma (ICP) chamber to generate a dangling bond (or a hybrid bond) on the surfaces of the substrates W1 and W2. However, the plasma generated by the plasma treating apparatus 21 is not limited to the induced-coupled plasma, and may be, for example, capacitively coupled plasma or microwave plasma.

The cleaning apparatus 23 may clean the surfaces of the substrates W1 and W2 that have been plasma treated by the plasma treating apparatus 21. The cleaning apparatus 23 may coat DIW (Deionized Water) on the surfaces of the substrates W1 and W2 using a spin coater. The DIW may not only clean the surface of the substrates W1 and W2, but may also ensure that hydroxyl (—OH) groups are well bonded to the surfaces of the substrates W1 and W2, such that the dangling bond may be formed more easily on the surfaces of the substrates W1 and W2.

The substrate bonding apparatus 25 may bond the two substrates W1 and W2 to each other in a wafer-to-wafer scheme of directly bonding the two substrates W1 and W2 that have been plasma treated by the plasma treating apparatus 21 and been cleaned by the cleaning apparatus 23 without a separate medium. That is, the substrate bonding apparatus 25 may bond the two substrates W1 and W2 to each other without using a bonding medium such as an adhesion film or a solder bump.

In order to perform a simple wafer-to-wafer scheme, the substrate bonding apparatus 25 may include a plurality of chucks (a first chuck 110 and a second chuck 210) for respectively supporting the two substrates W1 and W2 and a component (e.g., a top pusher 220) that presses the substrates W1 and W2.

Hereinafter, the substrate bonding apparatus 25 will be described with reference to the drawings.

FIG. 2 is a diagram for illustrating a substrate bonding apparatus according to some embodiments of the present disclosure.

Referring to FIG. 2, the substrate bonding apparatus 25 may include a body 25P, a stage 25M, a gantry 25G, a vision unit 25V, a lower module 100, and an upper module 200.

The body 25P may support the stage 25M and the gantry 25G thereon. According to some embodiments, the body 25P may be provided with a pneumatic system to move the stage 25M pneumatically.

The stage 25M may be provided on a top of the body 25P. In an example, a multi-axis motor may be provided to the stage to enable six (6) degrees of freedom movement thereof. Under an operation of this stage 25M, a height/position/orientation of the lower module 100 may be adjusted relative to the upper module 200.

The gantry 25G may be provided on a top of the body 25P and may support the vision unit 25V and the upper module 200. For example, the gantry 25G may have an opening open in a transfer direction of the substrates W1 and W2 so that the substrates W1 and W2 may be introduced into the opening by a transfer robot of the second transfer module 35.

The vision unit 25V may be configured to sense the substrates W1 and W2 and may be embodied as a camera, for example. Although not shown in the drawing, a mark may be provided on the substrates W1 and W2. Thus, a shape and a size of a chip, and/or a scale-compensation of the substrates W1 and W2/a pattern may be sensed/determined based on an imaging result of the mark and/or the chip using the vision unit 25V.

The lower module 100 and the upper module 200 may be arranged vertically and spaced apart from each other. The first substrate W1 placed on a top of the lower module 100 and the second substrate W2 placed on a bottom of the upper module 200 may be bonded to each other using a covalent bonding scheme.

An example in which in the substrate bonding apparatus 25 for bonding the first substrate W1 and the second substrate W2 to each other, the lower module 100 is disposed under the upper module 200 and includes a first chuck 110, a fluid control unit or fluid control system 120 and a deformable plate 140, and the upper module 200 is disposed on top of the lower module 100 and includes a second chuck 210 and the top pusher 220 is described below. However, embodiments of the present disclosure are not limited thereto.

For example, in a modified embodiment, the first chuck 110, the fluid control unit 120, and the deformable plate 140 may be disposed on top of the top pusher 220. In other words, the lower module 100 and the upper module 200 may be turned upside down. Thus, it should be noted that the substrate bonding apparatus 25 may have various modified embodiments.

Hereinafter, the lower module 100 will be described with reference to the drawings.

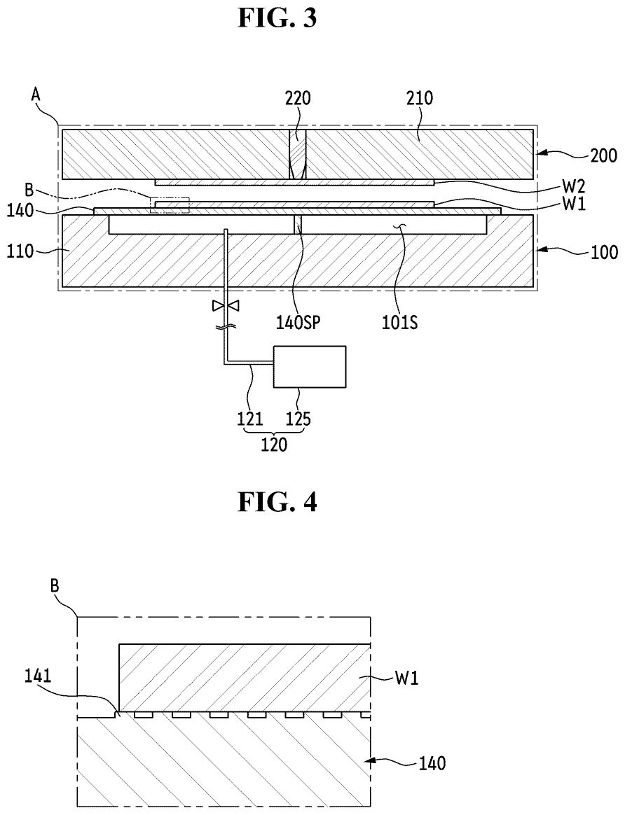

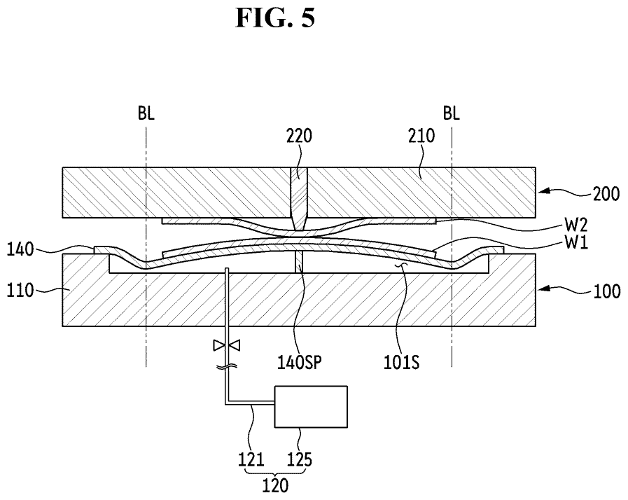

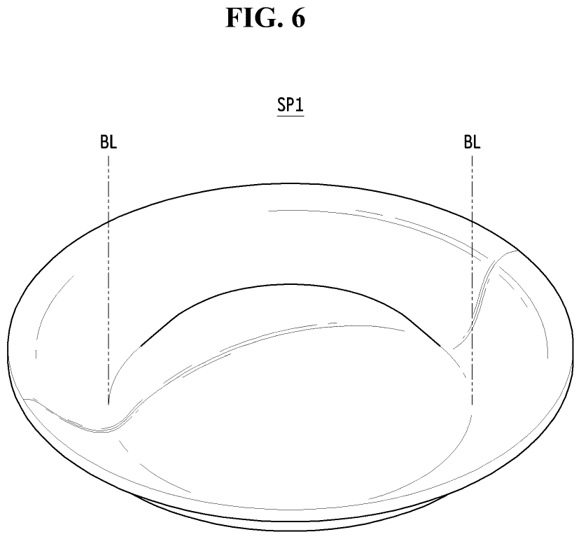

FIG. 3 is a diagram showing an area A of FIG. 2, and FIG. 4 is a diagram showing an area B of FIG. 3. FIG. 5 is a diagram showing a state in which centers of a first substrate and a second substrate are bonded to each other in the substrate bonding apparatus according to some embodiments of the present disclosure. FIG. 6 is a diagram showing an upper space shape of a deformable plate of the substrate bonding apparatus according to some embodiments of the present disclosure.

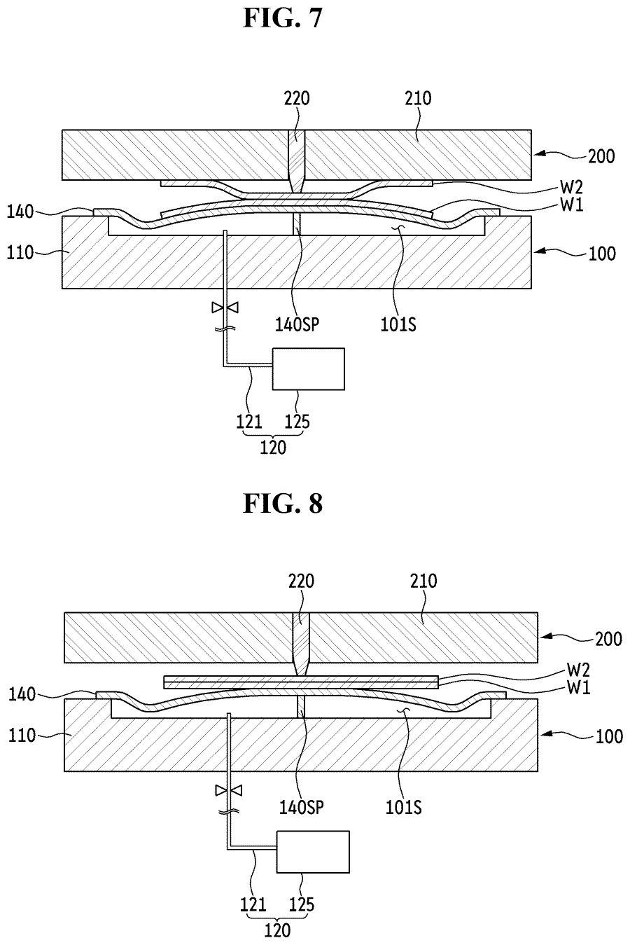

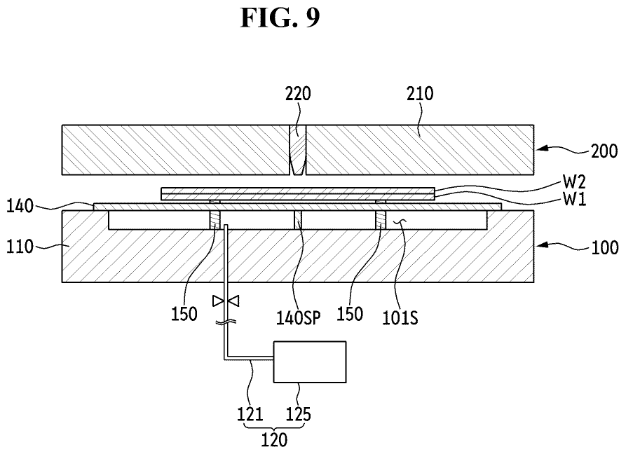

FIG. 7 is a diagram showing a process of attaching the second substrate to the first substrate in the substrate bonding apparatus according to some embodiments of the present disclosure. FIG. 8 is a diagram for illustrating a state in which the first substrate and the second substrate have been bonded to each other in the substrate bonding apparatus according to some embodiments of the present disclosure. FIG. 9 is a diagram showing a state in which lift pins protrude in the substrate bonding apparatus according to some embodiments of the present disclosure.

Referring to FIG. 3 to FIG. 9, the substrate bonding apparatus 25 according to some embodiments of the present disclosure includes the lower module 100 and the upper module 200.

The lower module 100 according to some embodiments may include the first chuck 110, the fluid control unit 120, and the deformable plate 140.

The first chuck 110 may be disposed on the stage 25M (see FIG. 2) and may be raised and lowered under the operation of the stage 25M and may have a larger diameter than that of the first substrate W1. For example, when the diameter of the first substrate W1 is 30 cm, the diameter of the first chuck 110 may be in a range of 35 cm to 40 cm.

The first chuck 110 may be provided with a first vacuum pump to vacuum-suction the first substrate W1 on the deformable plate 140. The first vacuum pump may apply vacuum pressure for vacuum-suction or remove vacuum pressure to remove vacuum-suction.

However, the present disclosure is not limited to a configuration in which each of the first chuck 110 and the second chuck 210 has each of the first vacuum pump and a second vacuum pump to support each of the first and second substrates W1 and W2. For example, a mechanical clamping scheme may be implemented as long as it does not conflict with the example embodiments. In this regard, the first chuck 110 may vacuum-suction the first substrate W1 via the deformable plate 140.

The deformable plate 140 may support the first substrate W1 thereon. The deformable plate 140 may have multiple vacuum holes defined therein for vacuum-suction of the first substrate W1. In addition, the deformable plate 140 may have embossing and/or a dam 141 (e.g., with alternating grooves) formed on an upper surface as a suction surface thereof to prevent the first substrate W1 from bending in a specific direction or receiving an external force during vacuum-suction (see FIG. 4).

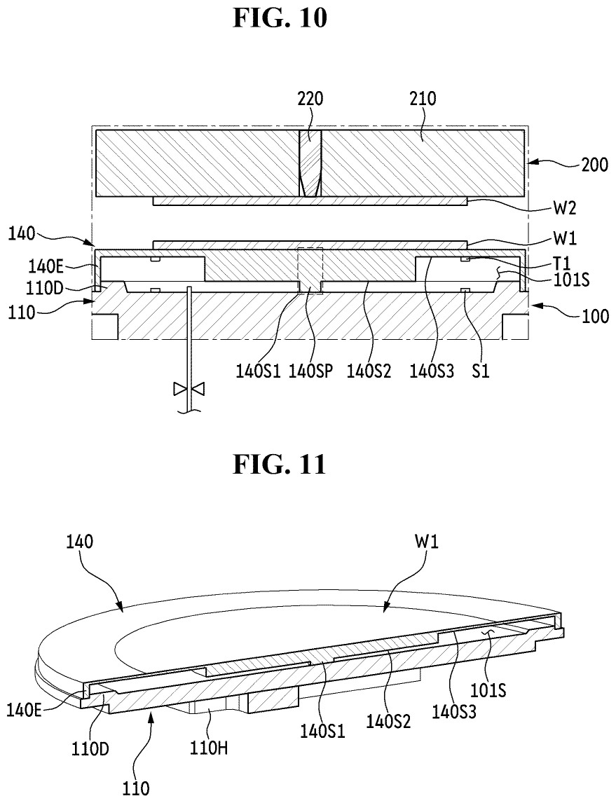

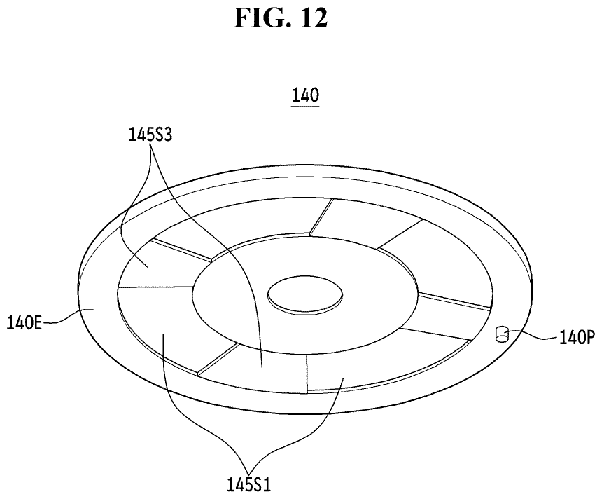

The deformable plate 140 may be provided on top of the first chuck 110. The deformable plate 140 may be fixed using the first chuck 110 and a clamp. Alternatively. a structure in which the clamp is omitted may be provided, which will be described with reference to FIG. 10 and FIG. 11.

The deformable plate 140 may have a deformable shape. The deformable plate 140 may be constructed such that a flat scale plate is at least partially deformed into a convex hemispherical shape (e.g., upwardly convex) so as to provide a scale-compensation of the first substrate W1 in a corresponding manner to the deformation of the second substrate W2.

For example, the deformable plate 140 may be embodied as a scale plate made of aluminum or silicon carbide (SiC). However, this is only an example, and embodiments of the present disclosure are not limited thereto.

At least a portion of the deformable plate 140 may be supported on the first chuck 110 so that at least a partial area of the deformable plate 140 may be deformed into a hemispherical shape around a center thereof. This will be described later with reference to FIG. 10 and FIG. 11.

When at least a portion of the deformable plate 140 has been deformed into the convex hemispherical shape, the first substrate W1 supported on the deformable plate 140 may be deformed into a convex hemispherical shape corresponding to the shape of the portion of the deformable plate 140 (See FIG. 5).

The fluid control unit 120 may be configured to adjust the scale-compensation of the first substrate W1, that is, to change the shape of the deformable plate 140, and to apply a negative pressure to a first space 101S between the first chuck 110 and the deformable plate 140. In other words, the fluid control unit 120 applies the negative pressure to the first space 101S to cause the deformable plate 140 to be partially depressed or pulled down to change the shape of the deformable plate 140, or to bring the pressure of the first space 101S into an atmospheric pressure to return the shape of the deformable plate 140 to a flat shape.

The fluid control unit 120 may control the first space 101S not with a positive pressure but with the negative pressure, thereby reducing the risk of explosion or damage due to the pressure application, so that a structure of the substrate bonding apparatus 25 may be stabilized.

In some embodiments, the fluid control unit 120 may include a first line 121 and a fluid controller 125.

The first line 121 may be in communication with the first space 101S, and fluid such as air and/or inactive or inert gas may flow through the first line.

The fluid controller 125 may be connected to the first line 121 and may discharge the fluid in the first space 101S through the first line 121 so that the negative pressure is applied to the first space 101S. The fluid controller 125 may apply the negative pressure to the first space 101S to generate a vacuum atmosphere in the first space 101S, or remove the vacuum pressure so that the first space 101S has the atmospheric pressure.

However, in some embodiments the first space 101S having the atmospheric pressure may be achieved by stopping the operation of the fluid controller 125 and introducing external air into the first space 101S through a separate line. The fluid controller 125 may be, for example, a vacuum pump, but is not limited thereto. Various devices by which a state of the first space 101S may be brought into the vacuum atmosphere may be used.

The upper module 200 may include the second chuck 210 and the top pusher 220.

The second chuck 210 may support the second substrate W2 facing the first substrate W1.

The second chuck 210 may be disposed on the gantry 25G and may have a larger diameter than that of the second substrate W2. The second chuck 210 may be provided with the second vacuum pump identical/similar to the first vacuum pump to vacuum-suction the second substrate W2 in the same or similar manner as the first chuck 110 may do. The second vacuum pump may apply vacuum pressure for vacuum-suction or remove vacuum pressure to remove vacuum-suction.

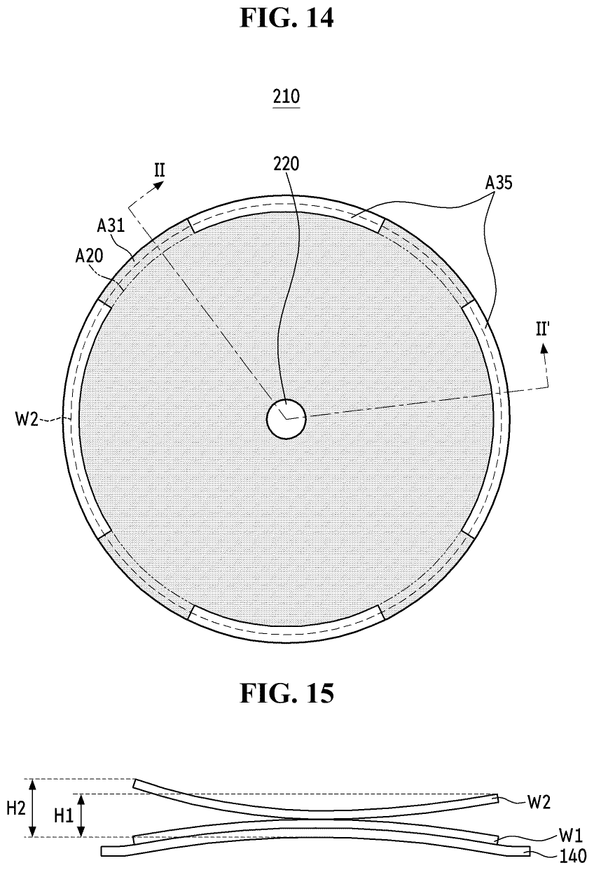

According to some embodiments, the second chuck 210 does not vacuum-suction an entire surface of the second substrate W2, but vacuum-suctions a partial area of the second substrate W2 so as to adjust the scale-compensation, and removes the vacuum-suction of the remaining area. This will be described with reference to FIG. 14 and FIG. 15.

The top pusher 220 may extend through the second chuck 210 to push the second substrate W2 in a downward direction. However, regarding the push operation of the top pusher 220, embodiments of the present disclosure are not limited to a configuration in which the upper module 200 presses the second substrate W2 in the downward direction. In another example, a pressurizing mechanism or member that is inflated through air or gas injection is disposed, so that the second substrate W2 may be bonded to the first substrate W1 in a starting manner from the center area of the substrate to the edge thereof under the inflating action of the pressurizing mechanism or member. That is, various modified embodiments regarding the push operation of the top pusher 220 may be implemented.

Furthermore, the top pusher 220 is illustrated as having a pin shape. However, various modified embodiments in which, for example, the top pusher 220 is embodied as a hollow pillar (e.g., a cylindrical pillar) having a lower surface of a ring cross-section in a plan view may be implemented.

This substrate bonding apparatus 25 may perform the bonding process as follows.

Referring to FIG. 3, the first substrate W1 may be vacuum-suctioned and supported on the lower module 100, and the second substrate W2 may be vacuum-suctioned and supported on the upper module 200.

In this regard, the fluid control unit 120 of the lower module 100 may not apply the negative pressure to the first space 101S, that is, to allow the first space 101S to have the atmospheric pressure, so that the shape of the deformable plate 140 is in a flat state.

In addition, the top pusher 220 of the upper module 200 may not press the second substrate W2. That is, the lower module 100 and the upper module 200 may only vacuum-suction the first substrate W1 and the second substrate W2, respectively, so that both the first substrate W1 and the second substrate W2 are in a flat state.

Next, referring to FIG. 5, the fluid control unit 120 of the lower module 100 may control a pressure in a feedback control manner in response to results detected in real time by a sensor unit or sensor system S1 and T1 (similar to FIG. 10) such that the negative pressure is applied to the first space 101S. That is, the fluid control unit 120 may adjust a vertical displacement of the deformable plate 140 by controlling a magnitude of the negative pressure.

In this regard, the deformable plate 140 may be partially depressed or pulled downward to due to the vacuum atmosphere of the first space 101S, that is, due to the application of the negative pressure of the fluid control unit 120 thereto, so that at least a partial area of the deformable plate 140 has been deformed into a hemispherical shape.

Referring to FIG. 5 and FIG. 6, the at least a partial area of the deformable plate 140 being deformed into the hemispherical shape may mean that an edge area or region of the deformable plate is depressed down based on the first support 140SP provided on a center area or region of the deformable plate 140 (or a center area of the first chuck 110) and the edge of the deformable plate 140, such that an area inwardly of a depress down reference line BL has a hemispherical shape.

In other words, as referring to FIG. 5 and FIG. 6, the deformable plate 140 may be depressed down due to the application of the negative pressure to the first space 101S, such that an upper surface shape SPI of the deformable plate 140 may be deformed from a flat plane into a shape with a curved surface. This deformable plate 140 may have a dome shape in an area (the area inwardly of the depress down reference line BL) facing the first substrate W1.

A point at which the change in the vertical dimension of the deformable plate 140 which has sunk down is greatest, that is, the lowest point (depress down reference line BL) of the edge area may be positioned at the same position as a position of an edge of the first substrate W1, or may be positioned outside the edge of the first substrate W1 such that the first substrate W1 has the hemispherical shape, and thus, the edge of the first substrate W1 may be prevented from rising again in the upward direction.

After the deformation of the deformable plate 140 has been completed such that the first substrate W1 is also deformed into the hemispherical shape, the second substrate W2 vacuum-suctioned onto the upper module 200 may protrude downwards in a center area thereof by the top pusher 220. In this regard, the center area of the second substrate W2 may be in contact with a center area of the first substrate W1 which has been deformed into the hemispherical shape.

According to some embodiments, after the deformation of the deformable plate 140 has been completed and before the center area of the second substrate W2 protrudes downwards by the top pusher 220, the stage 25M may be raised such that a vertical level of the deformable plate 140 may be adjusted.

Next, referring to FIG. 7, the hydroxyl group (—OH) generated on the surfaces of the substrates W1 and W2 may create a dangling bond on the surfaces of the substrates W1 and W2, such that a bonding area between the substrates W1 and W2 may spread outwardly. Then, as shown in FIG. 8, bonding between the substrates W1 and W2 may be completed.

Next, referring to FIG. 9, the bonded substrates W1 and W2 may be transferred by the transfer robot (see FIG. 1) of the second transfer module 35. To this end, a shape of the deformable plate 140 may return to a flat shape, and the substrates W1 and W2 may be lifted up and may be removed from the deformable plate 140 by the lift pins 150.

In this regard, the return of the shape of the deformable plate 140 to its flat shape may be achieved by returning the pressure of the first space 101S to the atmospheric pressure.

Hereinafter, various modified embodiments will be described with reference to the drawings, and duplicate descriptions of the same component performing the same function may be omitted in the interest of brevity.

FIG. 10 is a diagram for illustrating a substrate bonding apparatus according to some embodiments of the present disclosure, and FIG. 11 is a diagram for illustrating the lower module of the substrate bonding apparatus according to some embodiments of the present disclosure.

Referring to FIG. 10 and FIG. 11, the lower module 100 according to some embodiments may include the first chuck 110, the deformable plate 140, and the fluid control unit 120 as described with reference to FIG. 3 to FIG. 9.

The deformable plate 140 may have a structure in which a shape transformation of the deformable plate 140 may be greater in an edge area 140S3 thereof in a corresponding manner to the edge area of the first substrate W1. That is, a thickness of the edge area 140S3 of the deformable plate 140 may be smaller than a thickness of a center area 140S1 of the deformable plate 140 so that the shape transformation of the edge area 140S3 is greater than that of the center area 140S1.

This means that a depressing force applied to a cross section of the deformable plate 140 is inversely proportional to the elastic modulus depending on the material of the deformable plate 140, and the thickness thereof. Thus, the scale-compensation may be adjusted by varying the thickness of the deformable plate 140 in proportion to the negative pressure of the first space 101S.

In addition, the deformable plate 140 may have a step formed in a middle or intermediate area or region S140S2 between the center area or region 140S1 and the edge area or region 140S3. That is, the deformable plate 140 may have a stepped structure in which the thickness becomes smaller step by step as the plate 140 extends in a direction from the center area 140S1 to the edge area 140S3, so that the scale-compensation increases as the plate 140 extends in a direction from the center area 140S1 to the edge area 140S3.

Accordingly, the deformable plate 140 may be more easily deformed to form the hemispherical shape with a small height, such as smaller than 1 cm, compared to the substrates W1 and W2 having a diameter of 30 cm (12 inches).

The deformable plate 140 may be provided with a first support 140SP in the center area 140S1 to prevent the center area 140S1 from being depressed or pulled down even when the first space 101S has a vacuum atmosphere due to the application of the negative pressure thereto. In other words, the deformable plate 140 may be provided in a structure in which the edge area is depressed down relative to the center area where the first support 140SP is provided.

In addition, regardless of the vacuum atmosphere of the first space 101S, and whether the vacuum atmosphere of the first space 101S is removed or not, the deformable plate 140 may have a structure that the plate 140 is simply supported by the first chuck 110 and is not removed from the first chuck 110.

For example, the deformable plate 140 may be free of the clamp and, rather, a second support 140E may be provided on the edge thereof. The second support 140E may protrude toward the first chuck 110 and extend along the edge of the deformable plate 140, and may have a ring shape, for example. The heights of the second support 140E and the first support 140SP may be equal to each other so that bottoms of the second support 140E and the first support 140SP are at the same vertical level and tops thereof are at the same vertical level.

Further, the first chuck 110 may include an edge ring 110D surrounded with the second support 140E in a corresponding manner to the second support 140E.

In this way, the second support 140E and the edge ring 110D may contact and face each other in the direction of gravity/depress down, such that the first space 101S may be maintained as a closed space by the second support 140E and the edge ring 110D facing each other. In addition, the edge of the deformable plate 140 may be in a fixed state to the first chuck 110 regardless of whether the vacuum atmosphere of the first space 101S is removed or not in the same/similar manner as/to the center area 140S1 of the deformable plate 140.

Further, the first chuck 110 may include the sensor unit or system S1 and T1. For example, when bonding the substrates W1 and W2 that require shape compensation to each other, the first substrate W1 first is vacuum-suctioned to the deformable plate 140, and then the negative pressure is applied to the first space 101S to allow the deformable plate 140 to be partially depressed down. In this regard, a pressure application may be performed under a condition similar to a pressure of a preset value (e.g., empirically known process condition) in order to increase the number of times per hour of a bonding process. However, the sensor unit S1 and T1 may be provided for precise control of the pressure.

The sensor unit S1 and T1 may detect a vertical level of the deformable plate 140 and may include a first sensor S1 and a first sensing target T1.

The first sensor S1 may be provided on an upper surface of the first chuck 110 at a corresponding position to the edge of the first substrate W1. Accordingly, the dome shape of the deformable plate 140 may be detected based on change in a vertical level at a position vertically overlapping a position of the edge of the first substrate W1 relative to a vertical level of the center area of the deformable plate 140 without the shape deformation.

In addition, a plurality of the first sensors S1 may be provided. For example, 4 to 8 first sensors may be arranged on the upper surface of the first chuck and along and under the edge of the first substrate W1 (e.g., circumferentially spaced apart). Thus, hardware problems may be monitored in real time using the first sensors when bonding the substrates W1 and W2 to each other.

The first sensor S1 may be embodied as a sensor with a resolution, repeatability, and hysteresis smaller than 100 nm to enable ECAT communication, and may be embodied as, for example, a capacitive sensor, interferometer, a confocal displacement sensor, or an eddy current sensor. However, when the deformable plate 140 is made of a ceramic material, it may be difficult for the capacitance sensor to detect the ceramic material Accordingly, in order that the first sensor S1 may detect a metal, the first sensing target T1 may be made of a metal material and may be disposed at a position vertically overlapping the first sensor S1.

That is, the first sensing target T1 may be disposed on a lower surface of the deformable plate 140 and may have a sensing target surface to be sensed by the first sensor S1. Metal powders may be coated on the first sensing target, or a metal-coated sticker may be attached thereto. Some modified embodiments including a configuration in which a metal plate is bonded to the first sensing target may be implemented.

Furthermore, the sensor unit S1 and T1 may include a grounding structure received in the first chuck 110 to reduce fluctuations due to a factor such as hysteresis of an electrical transmission signal. A grounding cable of the grounding structure may be provided to have a feed-through structure in which an outside of the first chuck 110 and the first sensing target T1 are connected to each other to prevent leakage.

The fluid control unit 120 may perform feedback based on the change in the vertical level as detected by the sensor unit S1 and T1. A feedback control structure may be embodied as a PID control sequence and may detect the vertical level of the deformable plate 140 in real time based on a measuring result of a displacement of the first sensing target T1 in real time. When the vertical level value of the deformable plate 140 at the time of detection is greater than a specified recipe value, that is, is greater than a preset value, the feedback control structure may subtract a pressure corresponding to a minimum resolution of a regulator from the applied pressure so that the vertical level of the deformable plate 140 reaches the preset value. When the vertical level value of the deformable plate 140 at the time of detection is smaller than the specified recipe value, the feedback control structure may add the pressure corresponding to the minimum resolution of the regulator to the applied pressure so that the vertical level of the deformable plate 140 reaches the preset value.

In addition, a chuck holder 110H connecting the first chuck 110 and the stage 25M to each other may be fixed to the first chuck 110 in a vacuum-suction manner so that bolting coupling is omitted. However, embodiments of the present disclosure are not limited thereto.

Hereinafter, some further embodiments of the deformable plate 140 will be described with reference to the drawings, and duplicate descriptions of the same component that performs the same functions as the previously described embodiments may be omitted in the interest of brevity.

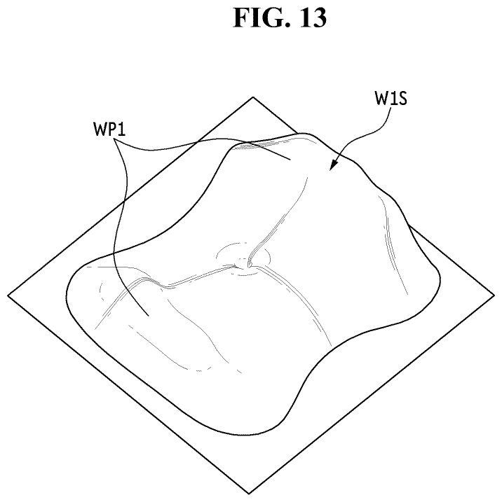

FIG. 12 is a diagram for illustrating a deformable plate of a substrate bonding apparatus according to some embodiments of the present disclosure, and FIG. 13 is a diagram for illustrating a saddle substrate.

Referring to FIG. 12, the substrate bonding apparatus 25 is the same/similar as/to those described above and may include the body 25P, the stage 25M, the gantry 25G, the vision unit 25V, the lower module 100 and the upper module 200.

The deformable plate 140 as illustrated in FIG. 12 may include first scale-compensation area 145S1 and second scale-compensation area 145S3 which are arranged alternately with each other in a clockwise/angular or circumferential direction. The first scale-compensation area 145S1 may have a smaller thickness than that of the second scale-compensation area 145S3. Accordingly, in order to cope with the first substrate W1 such as the saddle substrate W1S distorted due to warpage, a warpage area WP1 protruding by a large warpage may be distinguished from an area with a small warpage, and then, different scale-compensation may be applied to the warpage area WP1 and the area with the small warpage.

In this regard, as shown in FIG. 13, the saddle substrate W1S may refer to a substrate that has a horse saddle shape due to the occurrence of the warpage area WP1 protruding by the large warpage resulting from different curvatures of the first substrate W1 due to the warpage phenomenon.

In addition, the second support 140E may be constructed to prevent the deformable plate 140 from rotating arbitrarily. For example, the second support 140E may be provided with a fixing pin 140P that is inserted into the first chuck 110. The fixing pin 140P may pass through each of the second support 140E and the first chuck 110 to prevent the deformable plate 140 from rotating arbitrarily on the first chuck 110.

The structure for preventing the deformable plate 140 from rotating arbitrarily is not limited to a structure in which the fixing pin 140P passes through each of the second support 140E and the first chuck 110, and, for example, may be embodied as a structure that protrudes from a bottom of the second support 140E.

In some embodiments, although not shown in the drawing, a notch may be formed in each of the second support 140E and the first chuck 110 to prevent rotation of the second support 140E. Alternatively, epoxy bonding between the second support 140E and the first chuck 110 may be made so that the deformable plate 140 cannot rotate arbitrarily. In this way, various modified embodiments may be implemented.

Other embodiments may be implemented by combining elements or features of the substrate bonding apparatus of the various example embodiments described herein and/or a known scheme. For example, the deformable plate 140 of FIGS. 10 and 11 and the deformable plate 140 of FIG. 12 may be combined with each other so that the deformable plate 140 has a greater deformation of the edge area 140S3 than that of the center area 140S1. And the thickness of the edge area 140S3 may be smaller than the thickness of the center area 140S1 of the deformable plate 140, and/or a thickness of the first scale-compensation area 145S1 and a second scale-compensation area 145S3 may be different from each other.

Further, the fixing pin 140P of FIG. 12 may be provided on the deformable plate 140 of FIGS. 10 and 11.

In other words, another embodiment may be achieved by combining at least two of the example embodiments of the present disclosure and known schemes.

Hereinafter, the upper module 200 is described with reference to the drawings.

FIG. 14 is a plan view showing the upper module according to some embodiments of the present disclosure, and FIG. 15 is a diagram showing the second substrate corresponding to a cutting surface of II-II′ in FIG. 14.

Referring to FIG. 14 and FIG. 15, according to some embodiments, the second chuck 210 of the upper module 200 does not vacuum-suction an entire surface of the second substrate W2, but vacuum-suctions a partial area thereof and removes vacuum-suctioning of the remaining area in order to adjust the scale-compensation.

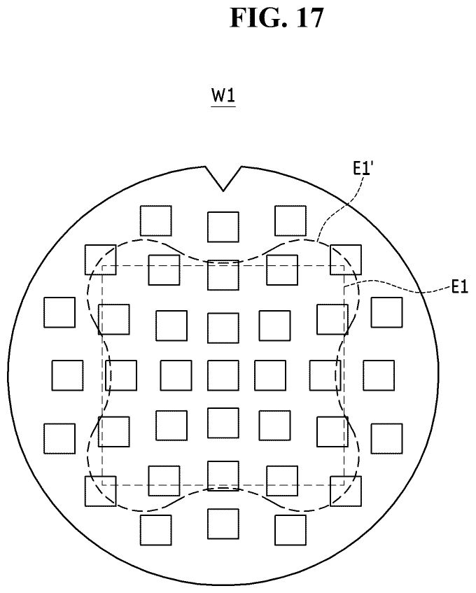

For example, in the first substrate W1 (see FIG. 17), under-deformation may occur in a specific area adjacent to a reference line E1 of the edge area. In other words, a reference line E1 of the edge area may be converted to a reference line E1′ of the edge area due to the under-deformation, as shown in an example of FIG. 17. Thus, the edge area may be deformed into a butterfly shape.

Thus, a scale-compensation may be applied in a corresponding manner to the first substrate W1 whose the edge area is deformed into the butterfly shape. To this end, when bonding the second substrate W2 to the first substrate W1, an edge of the second substrate W2 in a first area A31 overlapping the under-deformation area of the first substrate W1 is subjected to vacuum-suction, while an edge of the second substrate W2 in a second area A35 overlapping an area other than the under-deformation area is not subjected to vacuum-suction.

As a result, when the edge of the second substrate W2 is displaced downwardly toward the first substrate W1, the edge of the second substrate W2 of the first area A31 is displaced downwardly toward the first substrate by a smaller amount than that of the edge of the second substrate W2 of the second area A35. Thus, the edge of the second substrate W2 in the first area A31 is positioned at a second vertical level H2, while the edge of the second substrate W2 of the second area A35 is positioned at a first vertical level H1 lower than H2. Thus, a vertical level of the edge of the first area A31 and a vertical level of the second substrate W2 of the second area A35 are different from each other. Accordingly, the scale-compensation may be adjusted by a factor such as acceleration of gravity.

However, this is only an example, and the second chuck 210 may vacuum-suction the entire surface of the second substrate W2. Alternatively, the second chuck 210 may vacuum-suction only the edge of the second substrate W2 and may not vacuum-suction an inner area A20 inwardly of the edge of the second substrate W2. In this way, various modified embodiments may be implemented.

A configuration in which the first areas A31 and the second areas A35 are arranged alternately circumferentially with each other along the edge of the second substrate W2 is shown in FIG. 14. However, the present disclosure is not limited thereto. A size and a location of the area(s) are not limited to the examples in the drawings.

Hereinafter, the first and second substrates W1 and W2 bonded to each other in the embodiments of the present disclosure will be described with reference to the drawings.

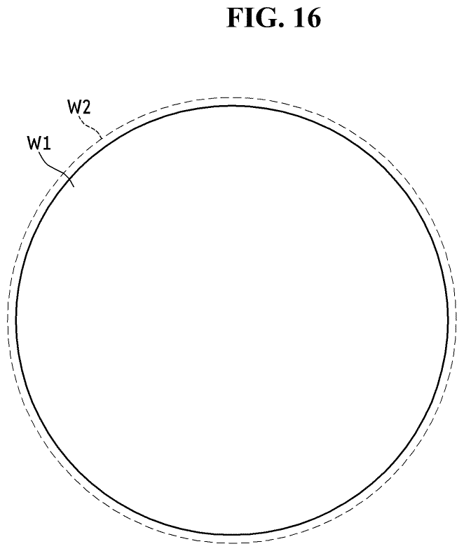

FIG. 16 is a diagram showing a ratio between areas in a plan view of the first substrate and the second substrate in a flat state. FIG. 17 is a diagram showing a state in which the first substrate is brought into a convex state by the deformable plate.

First, referring to FIG. 16, the first substrate W1 which is provided in a form of a flat plate has a smaller diameter than that of the second substrate W2. In a process in which the first substrate W1 is deformed into a convex hemisphere shape in a synchronized manner with the deformation of the deformable plate 140, an area of the first substrate W1 may increase to the area equal to an area of the second substrate W2.

For example, the second substrate W2 may have a radius of 30 cm, and the first substrate W1 may have a radius in range of 29.3 cm to 29.8 cm in a flat state.

A chip (see FIG. 17, no reference numeral) of the first substrate W1 which has been deformed into a convex shape may be bonded to a chip of the second substrate W2 in a corresponding manner to each other.

However, the first substrate W1 which has been deformed into the convex shape may have different deformation amounts depending on different areas, such as the center area and the edge area and/or as in the previously mentioned saddle substrate W1S. In this regard, a chip in an over-deformed or under-deformed area of the first substrate W1 may not be correctly aligned with the chip of the second substrate W2, which may reduce a product yield.

To prevent this situation, according to some embodiments the vacuum-suction amount may vary depending on the first area A31 and the second area A35 of the second chuck 210. In combination therewith or alternatively, the thickness of the first scale-compensation area 145S1 and the second scale-compensation area 145S3 of the deformable plate 140 may be different from each other such that corresponding scale-compensation may be different from each other.

Hereinafter, the substrate bonding apparatus 25 according to some embodiments will be described with reference to the drawings, and duplicate descriptions of the same component that performs the same function as the previously described embodiments may be omitted in the interest of brevity.

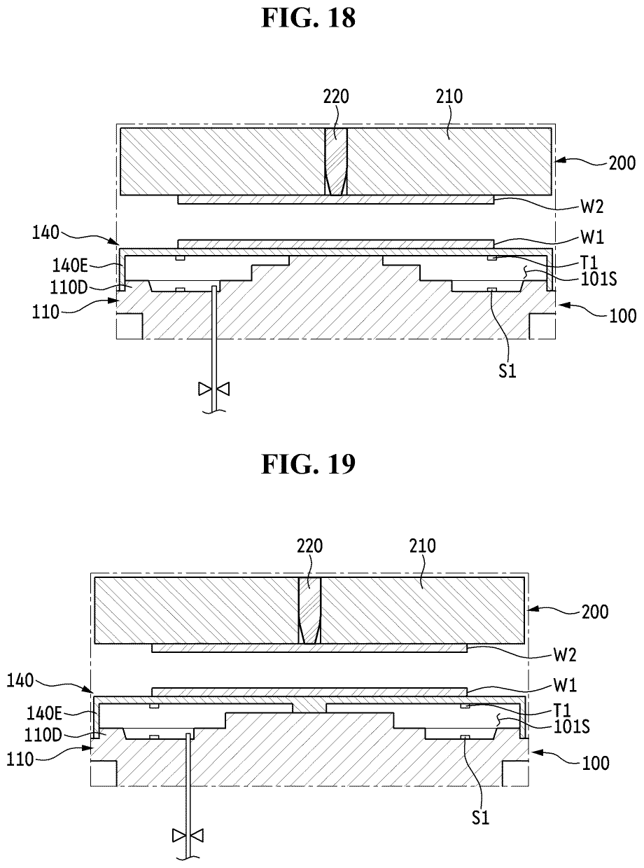

FIG. 18 is a diagram for illustrating a deformable plate of a substrate bonding apparatus according to some embodiments of the present disclosure. FIG. 19 is a diagram for illustrating a deformable plate of a substrate bonding apparatus according to some embodiments of the present disclosure.

Referring to FIG. 18 and FIG. 19, the substrate bonding apparatus 25 is the same as or similar to that of previously described embodiments and may include the body 25P, the stage 25M, the gantry 25G, the vision unit 25V, the lower module 100, and the upper module 200.

In some embodiments, the first chuck 110 may have a structure in which at least the center area protrudes upwardly.

For example, the first chuck 110 of the substrate bonding apparatus 25 may have a stepped structure in which a vertical dimension decreases step by step as the first chuck 110 extends from the center area toward the edge, as shown in FIG. 18. In this regard, the thicknesses of the center area, the middle area, and the edge area of the deformable plate 140 may be equal to each other.

However, the present disclosure is not limited thereto, and the embodiments of the present disclosure may be combined with each other to obtain other modified embodiments. Thus, embodiments in which the first chuck 110 has the stepped structure as described above and a structure of the deformable plate 140 is identical with the structure of the deformable plate 140 of FIGS. 10 and 11 in which the thickness thereof decreases step by step as the plate 140 extends from the area to the edge may be implemented.

Referring to FIG. 19, the first chuck 110 of the substrate bonding apparatus 25 may have a stepped structure in which the center area protrudes upwardly, and the deformable plate 140 of the substrate bonding apparatus 25 may not have the same thickness in the middle area and the edge area. In this regard, the center area of the deformable plate 140 may have a thickness larger than the thickness of the middle area and/or the edge area.

In this way, various modified embodiments in which the deformable plate 140 has the same thickness in the center area and the middle area, or has the same thickness in the center area and the edge area, or has the same thickness in the middle area and the edge area, or has the same thickness in the center area, the middle area, and the edge area may be implemented.

In addition, various modified embodiments in which the first chuck 110 has a flat upper surface or has a stepped structure in which the center area protrudes upwardly may be implemented.

Furthermore, in the stepped structure of the first chuck 110, the step may be small, such that the step may be formed as a curved portion.

In the substrate bonding apparatus 25 according to some embodiments, a dome shape may be formed due to the depression of the edge area of the deformable plate 140. Thus, the edge of the substrate W1 may have a shape that complies with a design, and a scale-compensation required for boding the substrates W1 and W2 to each other may be optimized.

Furthermore, in the substrate bonding apparatus 25 according to the embodiments of the present disclosure, the thicknesses of the center area and the edge area of the deformable plate 140 may be different from each other depending on a thickness gradient and distribution of the deformable plate 140. The thicknesses of the first scale-compensation area 145S1 and the second shape-compensation area 145S3 of the deformable plate 140 arranged in the circumferential manner may be different from each other. Thus, the scale-compensation amount applied to the first substrate W1 may be adjusted in a direction from the center to the edge thereof or in the circumferential direction. Thus, a scale-compensation required for boding the substrates W1 and W2 to each other may be optimized.

The substrate bonding apparatus 25 according to the embodiments of the present disclosure is free of the clamp and thus has a simplified structure, and does not cause fluid leakage out of a space under the deformable plate or deterioration of alignment accuracy due to clamp plane management. The substrate bonding apparatus 25 according to the present disclosure deforms the deformable plate 140 using the negative pressure such that deterioration in fluid control precision due to the fluid leakage is prevented, and the risk of explosion and/or damage due to pressure application is low, thereby improving structural reliability.

Although example embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A substrate bonding apparatus comprising:
a deformable plate configured to support a first substrate thereon and to be at least partially deformable;
a first chuck on one surface of the deformable plate such that a first space is defined between the deformable plate and the first chuck, wherein the first chuck has a diameter larger than a diameter of the first substrate; and
a fluid control unit configured to control inflow and outflow of fluid into and out of the first space,
wherein the fluid control unit is configured to control the inflow and the outflow of the fluid into and out of the first space so that a negative pressure is applied to the first space.

2. The substrate bonding apparatus of claim 1, wherein a thickness of an edge area of the deformable plate is smaller than a thickness of a center area or a middle area of the deformable plate.

3. The substrate bonding apparatus of claim 2, wherein the deformable plate or the first chuck has a first support extending vertically between the first chuck and the deformable plate so as to prevent the center area of the deformable plate from being deformed in the first space subjected to the negative pressure.

4. The substrate bonding apparatus of claim 2, wherein the deformable plate has a position in the edge area at which change in a vertical level thereof is greatest when the edge area has been deformed,
wherein the position vertically overlaps an edge of the first substrate or vertically overlaps a position positioned outwardly of the edge of the first substrate.

5. The substrate bonding apparatus of claim 2, wherein the deformable plate includes a step between a middle area and the center area, and a step between the edge area and the middle area.

6. The substrate bonding apparatus of claim 5, wherein a thickness of the deformable plate decreases step by step as the deformable plate extends outwardly.

7. The substrate bonding apparatus of claim 1, wherein the first chuck includes a sensor unit configured to detect change in a vertical level of the deformable plate,
wherein the sensor unit includes:
a first sensor on an upper surface of the first chuck and at a position vertically overlapping an edge of the first substrate; and
a first sensing target having a sensing target surface configured to be sensed by the first sensor and on a lower surface of the deformable plate.

8. The substrate bonding apparatus of claim 1, wherein the deformable plate includes a first scale-compensation area and a second scale-compensation area arranged in a circumferential direction of an edge area of the deformable plate,
wherein the first scale-compensation area has a smaller thickness than a thickness of the second scale-compensation area.

9. The substrate bonding apparatus of claim 1, wherein the deformable plate includes a second support extending from an edge area of the deformable plate toward the first chuck and extending along the edge area of the deformable plate.

10. The substrate bonding apparatus of claim 9, wherein the first chuck includes an edge ring surrounded by the second support.

11. The substrate bonding apparatus of claim 10, wherein the second support has a fixing pin configured to be inserted into the first chuck, or has a notch to prevent unintended rotation of the first chuck.

12. The substrate bonding apparatus of claim 1, wherein the fluid control unit includes:
a first line in communication with the first space; and
a fluid controller connected to the first line.

13. The substrate bonding apparatus of claim 1, further comprising a second chuck configured to support a second substrate,
wherein the first chuck is under the second chuck and faces the second chuck in a vertical direction.

14. A substrate bonding apparatus comprising:
a lower module configured to support a first substrate; and
an upper module including a second chuck configured to support a second substrate facing the first substrate,
wherein the lower module includes:
a deformable plate configured to support the first substrate thereon and to be at least partially deformable;
a first chuck under the deformable plate such that a first space is defined between the deformable plate and the first chuck, wherein the first chuck has a diameter larger than a diameter of the first substrate; and
a fluid control unit configured to control inflow and outflow of fluid into and out of the first space,
wherein the fluid control unit is configured to control the inflow and the outflow of the fluid into and out of the first space so that a negative pressure is applied to the first space.

15. The substrate bonding apparatus of claim 14, wherein the second substrate includes first areas and second areas arranged alternately with each other along an edge area thereof,
wherein the second chuck is configured to vacuum-suction each of the first areas of the second substrate, and not to vacuum-suction each of the second areas of the second substrate.

16. The substrate bonding apparatus of claim 14, wherein a thickness of an edge area of the deformable plate is smaller than a thickness of a center area of the deformable plate,
wherein the deformable plate includes:
a first support on the center area so as to contact the first chuck; and
a second support extending from the edge area toward the first chuck and extending along the edge area,
wherein the first chuck includes an edge ring surrounded by the second support.

17. The substrate bonding apparatus of claim 14, wherein the deformable plate has a position in an edge area at which change in a vertical level thereof is greatest when the edge area has been deformed,
wherein the position vertically overlaps an edge of the first substrate or vertically overlaps a position positioned outwardly of the edge of the first substrate.

18. The substrate bonding apparatus of claim 14, wherein the deformable plate includes a first scale-compensation area and a second scale-compensation area arranged in a circumferential direction of an edge area of the deformable plate,
wherein the first scale-compensation area has a smaller thickness than a thickness of the second scale-compensation area.

19. The substrate bonding apparatus of claim 14, wherein the fluid control unit includes a first line in communication with the first space, and a vacuum pump connected to the first line,
wherein the first chuck includes a sensor unit configured to detect change in a vertical level of the deformable plate,
wherein the sensor unit includes:
a first sensor on an upper surface of the first chuck and vertically overlapping an edge of the first substrate; and
a first sensing target having a sensing target surface configured to be sensed by the first sensor and on a lower surface of the deformable plate.

20. A substrate bonding apparatus for bonding a plasma-treated first substrate and a plasma-treated second substrate to each other, the apparatus comprising:
a lower module including a first chuck having a larger diameter than a diameter of the first substrate, wherein the first chuck is under the first substrate; and
an upper module including a second chuck configured to support the second substrate facing the first substrate,
wherein the lower module includes:
a deformable plate on top of the first chuck and configured to support the first substrate thereon and to be at least partially deformable, wherein a first space is defined between the deformable plate and the first chuck; and
a fluid control unit configured to control inflow and outflow of fluid into and out of the first space,
wherein the deformable plate includes a step between a middle area and a center area, and a step between an edge area and the middle area, wherein a thickness of the deformable plate decreases step by step in a radial outward direction,
wherein the deformable plate includes a first support in contact with the first chuck and disposed on the center area,
wherein the deformable plate includes a second support extending downwardly from the edge area toward the first chuck and extending along the edge area,
wherein the deformable plate has a position in the edge area at which the edge area has been depressed down by a greatest amount, wherein the position vertically overlaps an edge of the first substrate or vertically overlaps a position positioned radially outwardly of the edge of the first substrate,
wherein the deformable plate includes a first scale-compensation area and a second scale-compensation area arranged in a circumferential direction of the edge area of the deformable plate, wherein the first scale-compensation area has a smaller thickness than a thickness of the second scale-compensation area,
wherein the fluid control unit includes a first line in communication with the first space, and a vacuum pump connected to the first line, wherein the vacuum pump is configured to discharge the fluid out of the first space so that the deformable plate is partially depressed down,
wherein the first chuck includes an edge ring surrounded by the second support and a sensor unit configured to detect a vertical level of the deformable plate,
wherein the sensor unit includes:
a first sensor on an upper surface of the first chuck and at a position vertically overlapping the edge of the first substrate; and
a first sensing target defining a sensing target surface to be sensed by the first sensor and on a lower surface of the deformable plate.
